(19) United States
(12) Patent Application Publication
(10) Pub. No.: US 2004/0159938 A1
(43) Pub. Date: Aug. 19, 2004

(54) Semiconductor component and method for producing same

(75) Inventors: Harry Hedler, Germering (DE); Simon Muff, Hohenkirchen (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 10/721,787

(22) Filed: Nov. 26, 2003

(30) Foreign Application Priority Data
Nov. 29, 2002 (DE) 102 55 848.5

(51) Int. Cl. H01L 23/34

(52) U.S. Cl. 257/723; 257/730; 257/727

(57) ABSTRACT

The invention relates to a semiconductor component, in particular memory module, having a carrier board and semiconductor chips, in particular memory chips, the semiconductor chips being fitted on the carrier board such that the main planes thereof run perpendicular to the carrier boards. Furthermore, the invention relates to a method for producing semiconductor components.

### CLAIM FOR PRIORITY

This application claims priority to German Application No. 10255848.5 filed Nov. 29, 2002, which is incorporated herein, in its entirety, by reference.

### TECHNICAL FIELD OF THE INVENTION

The invention relates to a semiconductor component, and in particular a memory module, having a carrier board and semiconductor chips and to a method for producing semiconductor components.

### BACKGROUND OF THE INVENTION

SSTL (Series Stub Terminated Logic) topology represents an inexpensive and easily upgradeable solution for memory systems. At high clock frequencies, for example at clock frequencies above 150 MHz, the performance of such memory systems is restricted, however, since the memory controller (MC) can only handle a limited capacitive load. Thus, by way of example, SSTL topology for a DDR II (Double Data Rate) system at a clock rate of 266 MHz is limited to the use of four DRAM (Dynamic RAM) elements. Since conventional computer systems are usually provided with four slots for furnishing memory modules, it is thus possible either for two slots to be furnished with two memory elements in each case or for all four slots to be furnished with one memory element in each case.

The so-called SLT (Short Loop Through) bus topology has been proposed in order to eliminate this disadvantage. It is based on reducing the number of branch junctions needed to transport signals from the memory bus to the individual memory modules. In order to reduce signal reflections, a series of controller drivers are directly connected to each memory module for this purpose. What is disadvantageous about this solution is that with the number of connection pins at the connection piece (connector) remaining the same, the bus width is halved since the entire data bus has to be led through each memory module. A larger connection piece with more connection pins, which would make it possible to use the full bus width, would lead to problems, however, during production and during installation in the main board (Motherboard).

### SUMMARY OF THE INVENTION

The present invention increases storage density for SLT topologies.

In one embodiment of the invention, semiconductor chips are arranged directly on the carrier board (PCB, Printed Circuit Board), with the result that the use of the intermediate carriers provided hitherto on the carrier boards in corresponding slots for receiving the semiconductor chips is no longer necessary. With the space requirement on the main board remaining the same compared with conventional solutions, it is thus possible to achieve an increase in the storage density. At the same time, a stable environment is created for the SLT topology. By virtue of the individual semiconductor chips being arranged on edge, it is possible to obtain storage densities that have not been achieved hitherto in SLT topology. In this case, the memory/volume factor may be defined depending on the type of DRAM memory elements used.

Significantly, unlike hitherto, the semiconductor chips are not fitted with their main side flat on the intermediate carrier, rather the semiconductor chips are now arranged vertically on the carrier board, so that the main plane of the semiconductor chip running parallel to the main side runs perpendicular to the carrier board. In other words, the semiconductor chips are arranged on the carrier board such that they stand on one of their narrow sides.

The carrier board provided with semiconductor chips may be received as a memory module directly in corresponding receptacle devices of the main board. If it is arranged parallel to the main board in this case, only two connection pieces are required for the mounting of the carrier board. It is furthermore advantageous that the number of soldering points on the main board is thereby significantly reduced.

In one preferred refinement of the invention, the semiconductor chips are connected to the carrier board by means of soldered connections. The use of soldered connections guarantees a particularly reliable and long-lasting electrical connection between semiconductor chip and carrier board.

In a further preferred refinement of the invention, the semiconductor chips have printed lines on one of their main sides. The lines serve for electrically connecting the contact points of the semiconductor chips to contact areas of the carrier board. It is particularly advantageous if the printed lines run beyond the lower edges of the main sides of the semi-conductor chips onto the base sides of the semiconductor chips. The semiconductor chips can then be fixed on the carrier board in a particularly simple manner, since the semiconductor chip only has to be placed by its base side onto the corresponding contact areas of the carrier board and subsequently be soldered.

Another preferred refinement of the invention provides for two semiconductor chips in each case to be combined to form a chip composite. A so-called DDP (Double Density Package) system is thereby produced, which allows two semiconductor chips to be arranged on the same space as one conventional semiconductor chip. For this purpose, the two semiconductor chips are preferably connected to one another by an adhesive at their main sides free of contact points. The storage density can again be considerably raised through the use of such a chip composite. Furthermore, the performance of the memory system is increased and the cost risk in the production of the memory subsystem is reduced.

The invention furthermore relates to a method for producing semiconductor components. This method provides for electrical lines to be printed on the main sides of semiconductor chips and then for a chip composite to be produced by adhesively bonding two semiconductor chips in each case, which chip composite is subsequently fitted on a carrier board in such a way that the main planes of the semiconductor chips run perpendicular to the carrier board. Semiconductor components with particularly high storage density can be produced by such a method.

One advantage of the method is that the adhesive bonding of the semiconductor chips is effected in such a way that after the introduction an adhesive between the main sides of the semiconductor chips, the latter are brought together in an adhesive bonding mold in such a way that an at least partial encapsulation of the chip composite is produced. As a result, the chip composite is not only mechanically stabilized but also shielded from external influences. If an elastic adhesive is used, then it is furthermore possible also to compensate for alternating mechanical stresses on account of different coefficients of linear thermal expansion.

### BRIEF DESCRIPTION OF THE DRAWINGS

The invention is explained further below with reference to the drawing.

In this case:

FIG. 1 shows a side view of a memory chip with printed circuits.

FIG. 2 shows a plan view of a main side of the memory chip from FIG. 1.

FIG. 3 shows a side view of a chip composite at the beginning of the adhesive bonding process.

FIG. 4 shows a side view of a chip composite after the adhesive bonding process has concluded.

FIG. 5 shows a side view of a chip composite fitted on a carrier board.

FIG. 6 shows a plan view of a carrier board with a plurality of chip composites.

FIG. 7 shows a side view of a populated carrier board during installation onto a main board.

### DETAILED DESCRIPTION OF THE INVENTION

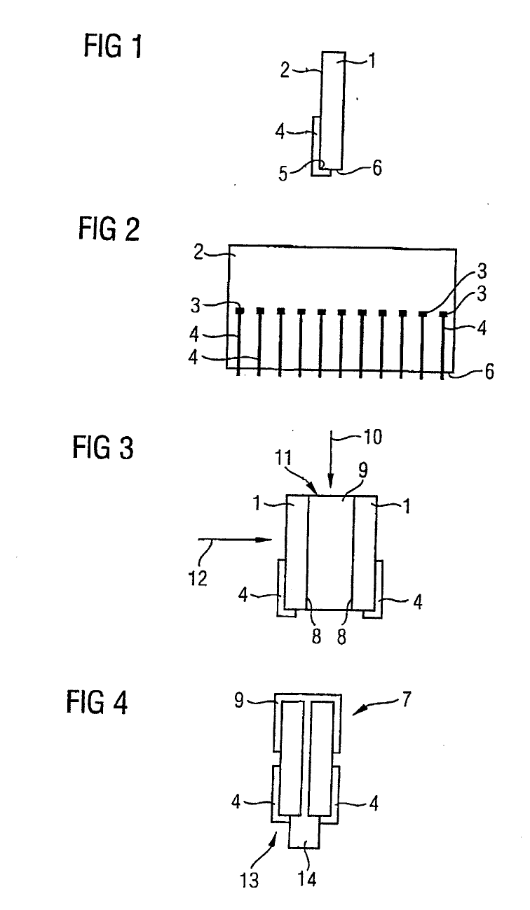

FIGS. 1 and 2 represent a memory chip 1 as is used for producing a memory module according to the invention. The memory chip 1 has contact points (pads) 3 on one of its main sides 2. Said contact points are provided with lines 4 in order to produce an electrical connection to the contact areas of a carrier board, which lines have previously been printed on the surface of the memory chip 1 by a suitable method. The printed lines 4 run beyond the lower edge 5 of the main side 2 of the memory chip 1 onto the base side 6 of the memory chip 1, so that the memory chip 1, for contact connection with the contact areas of the carrier board, merely has to be placed onto the carrier board by its base side 6.

FIGS. 3 and 4 show different phases in the process for producing a chip composite 7 comprising two memory chips 1. Accordingly, first of all the main sides 8 of the two memory chips 1 that are free of contact points are arranged in such a way that they point toward one another. The interspace 11 between the main sides 8 and the two memory chips 1 is then filled in a so-called underfill process and/or by injecting an adhesive 9 in injection direction 10. Afterward, the two memory chips 1 are joined together by being moved toward one another in pressure direction 12. In this case, the memory chips 1 are brought together in an adhesive bonding mold in such a way that an at least partial encapsulation of the chip composite 7 is produced by virtue of the adhesive 9 between the main sides 8 escaping into the adhesive bonding mold. An elastic separation element 14 in the form of an elevation projecting beyond the electrical lines 4 simultaneously forms at the base side 13 of the chip composite 7 between the electrical connection points of the two memory chips 1. Said separation element 14 serves not only for the insulation of the conductor tracks but also for mechanical stabilization during the mounting of the chip composite 7.

For the mounting of the chip composite 7, the latter is fitted in mounting direction 15 on a carrier board 16 and soldered. FIG. 5 shows a memory module 28 having a PCB carrier board 16 with a chip composite 7 fixed thereon. In this case, the lines 4 at the base side 6 of the memory chips 1 are connected by soldering points 17 to the corresponding contact areas 18 on the carrier board 16. The memory chips 1 are thus mounted with their main planes 19 perpendicular to the carrier board 16. The structural height 20 of such a chip composite 7 is 10 mm, for example.

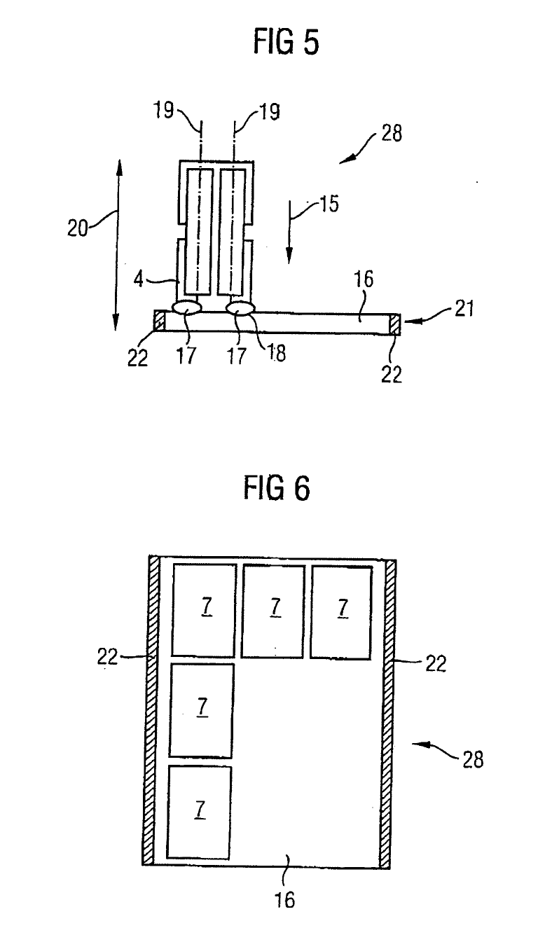

At its longitudinal sides 21, the carrier board 16 has contact elements 22 for making contact with edge connectors fitted on a main board. In this case, the contact elements 22 serve either for a purely mechanical safeguarding of the carrier board 16 or else at the same time for a fly-by-termination. FIG. 6 shows the way in which the chip composites 7 are arranged on the carrier board 16. Only five of them here, by way of example, nine possible locations are occupied in this case.

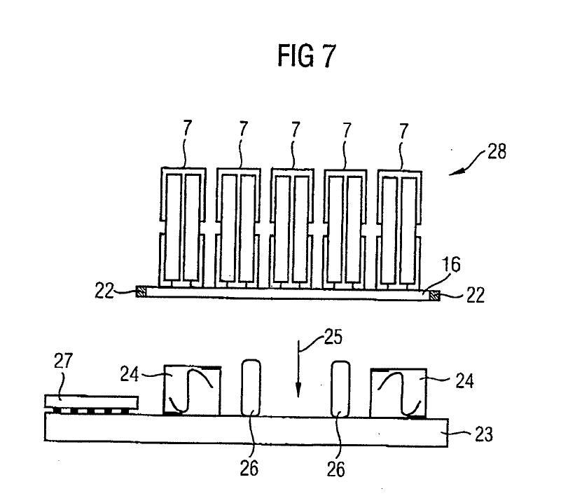

Finally, FIG. 7 shows the way in which the memory module, comprising the carrier boards 16 populated with the chip composites 7, is installed onto a PCB main board 23 of a computer system. Corresponding 90° SMT edge connectors 24 for the mounting of the carrier board 16 are fitted on the main board 23. For mounting purposes, the carrier board is fed in installation direction 25 onto the main board 23 until the contact elements 22 at the longitudinal sides of the carrier board 16 engage with the edge connectors 24. For the mechanical support of the carrier board 16, elastic supporting elements 25 are provided on the main board 24, the carrier board 16 bearing on the supporting elements in the mounted state. In the mounting end position, the carrier board 16 then runs parallel to the main board 23. The memory chips 1 are driven by means of a memory controller 27, which is arranged on the main board 23 and is connected to the memory chips 1 via the edge connectors 24 by means of the circuits printed on the main board 23.

List of Reference Symbols

1 Memory chip

2 Main side

3 Contact point

4 Line

5 Lower edge

6 Base side

7 Chip composite

8 Main side

9 Adhesive

10 Injection direction

11 Interspace

12 Pressure direction

13 Base side

14 Separation element

15 Mounting direction

16 Carrier board

17 Soldering point

18 Contact area

19 Main plane

20 Structural height

21 Longitudinal side

22 Contact element

23 Main board

24 Edge connector

25 Installation direction

26 Supporting element

27 Memory controller

28 Memory module

What is claimed is:

1. A semiconductor component comprising a carrier board and a plurality of semiconductor chips wherein the semiconductor chips are fitted on the carrier board such that main planes thereof run perpendicular to the carrier board.

2. The semiconductor component according to claim 1, wherein the semiconductor chips are connected to the carrier board by soldered connections.

3. The semiconductor component according to claim 1, wherein the semiconductor chips have printed lines on a respective main side for electrically connecting contact points of the semiconductor chips to contact areas of the carrier board.

4. The semiconductor component according to claim 3, wherein the printed lines run beyond lower edges of the main side onto base sides of the semiconductor chips.

5. The semiconductor components according to claim 1, wherein two of the semiconductor chips are combined to form a chip composite.

6. The semiconductor component according to claim 5, wherein the two semiconductor chips are connected to one another by an adhesive at main sides free of contact points.

7. A main board for a computer system, having a semiconductor component comprising a carrier board and a plurality of semiconductor chips, wherein the carrier board of the semiconductor component is arranged parallel to the main board.

8. A method for producing semiconductor components, comprising:
printing electrical lines of main sides of semiconductor chips such that the lines run from contact points of the semiconductor chips beyond lower edges of the main sides onto base sides of the semiconductor chips;
producing a chip composite by adhesively bonding together non-printed main sides of two semiconductor chips; and
fitting the chip composite on a carrier board such that main planes of the semiconductor chips run perpendicular to the carrier board.

9. The method according to claim 8, wherein the adhesive bonding comprises:
introducing an adhesive between the main sides of the semiconductor chips; and
bringing together the semiconductor chips in an adhesive bonding mold such that an at least partial encapsulation of the chip composite is produced.

10. The method according to claim 8, wherein the fitting of the chip composite comprises production of soldered connections between the printed lines and contact areas of the carrier board.
